(19) United States
(12) Patent Application Publication
(10) Pub. No.: US 2006/0102957 A1
(43) Pub. Date: May 18, 2006

(54) SER immune cell structure

(76) Inventor: Jhon-Jhy Liaw, Hsin-Chu (TW)

Correspondence Address: SLATER & MATSIL, L.L.P., 17950 PRESTON ROAD, SUITE 1000, DALLAS, TX, 75252, US

(21) Appl. No.: 10/988,262

(22) Filed: Nov. 12, 2004

(51) Int. Cl. H01L 29/94

(52) U.S. Cl. 257/368

(57) ABSTRACT

A semiconductor chip is provided, which includes a memory device formed in a deep NWELL region. The memory device includes a memory cell. The memory cell includes a first storage node and a second storage node. The memory cell also includes a first resistor and a second resistor electrically connected to the first storage node and the second storage node, respectively. The memory cell also includes a first capacitor and a second capacitor electrically connected to the first storage node and the second storage node, respectively. An inter-layer-dielectric (ILD) layer overlies the memory device. The ILD layer includes at least one boron-free dielectric material. An inter-metal-dielectric (IMD) layer overlies the ILD layer. The IMD layer has a dielectric constant that is less than about 3. A polyimide layer overlies the IMD layer. A thickness of the polyimide layer is less than about 20.

### TECHNICAL FIELD

The present invention relates generally to a system for semiconductor devices, and more particularly to a system for an SER Immune Cell Structure.

### BACKGROUND

Complementary metal-oxide-semiconductor (CMOS) technology is the dominant semiconductor technology used for the manufacture of ultra-large scale integrated (ULSI) circuits today. Size reduction of the semiconductor structures has provided significant improvement in the speed, performance, circuit density, and cost per unit function of semiconductor chips over the past few decades. Significant challenges, however, are faced as the sizes of CMOS devices continue to decrease.

One such challenge is soft errors. Soft errors are errors that occur in the logic state of a circuit due to excess charge carriers, which are typically induced by alpha particles and cosmic ray neutrons. As the excess charge carriers are induced into a circuit, the logic values may be altered. For example, a logic value of a capacitor or line may be altered from a logic “0” to a logic “1,” transistor gates may be turned off or on, or the like. Soft errors occurring in SRAM devices or other memory devices can cause the stored data to become corrupted.

Attempts have been made to limit the effect of excess charge carriers and soft errors on integrated circuits. One such attempt involves the addition of error-correcting circuitry (ECC). Another attempt involves lowering the size ratio for the pull up device to pull down devices sizes to below 0.75, in order to provide cell size reduction. These attempts, however, generally require additional circuitry, additional processing, and increased power requirements. Such requirements may adversely affect the design and fabrication of more robust memory circuits.

### SUMMARY OF THE INVENTION

These and other problems may be solved or circumvented, and technical advantages are generally achieved, by preferred embodiments of the present invention, which provide an SER immune cell structure.

In accordance with one aspect of the present invention, a semiconductor chip is provided, which includes a substrate, a first dielectric layer, and a polyimide layer. The first dielectric layer is overlying the substrate. The first dielectric layer has a dielectric constant that is less than about 3. The first dielectric layer includes a plurality of metal wires. The polyimide layer is overlying the first dielectric layer. A thickness of the polyimide layer is less than about 20 microns.

In accordance with another aspect of the present invention, a semiconductor chip is provided, which includes a substrate, a deep NWELL region in the substrate, a logic device, a first dielectric layer, and a polyimide layer. The logic device is in the deep NVVELL region. The first dielectric layer is overlying the logic device. The first dielectric layer has a dielectric constant that is less than about 3. The first dielectric layer includes a plurality of metal wires. The polyimide layer is overlying the first dielectric layer. A thickness of the polyimide layer is less than about 20 microns.

In accordance with yet another aspect of the present invention, a static random access memory (SRAM) chip is provided, which includes a substrate, a deep NWELL region in the substrate, an SRAM device, a first dielectric layer, and a polyimide layer. The SRAM device is in the deep NWELL region. The first dielectric layer is overlying the substrate. The first dielectric layer has a dielectric constant that is less than about 3. The first dielectric layer includes a plurality of metal wires. The polyimide layer is overlying the first dielectric layer. A thickness of the polyimide layer is less than about 20 microns.

In accordance with still another aspect of the present invention, a semiconductor chip is provided, which includes a substrate, a memory device, and a first dielectric layer. The memory device is in the substrate. The memory cell is in the memory device. The memory cell includes a first pass gate device, a second pass gate device, a first inverter, a second inverter, a first metal-insulator-metal (MIM) capacitor, a second MIM capacitor, a first storage node, and a second storage node. A first electrode of the first MIM capacitor has a first constant voltage. A first electrode of the second MIM capacitor has a second constant voltage. The first storage node includes a source node of the first pass gate device, an output of the second inverter, and a second electrode of the first MIM capacitor. The second storage node includes a source node of the second pass gate device, an output of the first inverter, and a second electrode of the second MIM capacitor. The first dielectric layer is overlying the memory device. The first dielectric layer has a dielectric constant that is less than about 3.

In accordance with yet another aspect of the present invention, a semiconductor chip is provided, which includes a substrate, a memory device, and a first dielectric layer. The memory device is in the substrate. A memory cell is in the memory device. The memory cell includes a first pass gate device, a second pass gate device, a first inverter, a second inverter, a first resistor, a second resistor, a first storage node, and a second storage node. A first node of the first resistor is electrically connected to an input of the first inverter. A first node of the second resistor is electrically connected to an input of the second inverter. The first storage node includes a drain node of the first pass gate device, an output of the second inverter, and a second node of the first resistor. The second storage node includes a drain node of the second pass gate device, an output of the first inverter, and a first node of the second resistor. The first dielectric layer is overlying the memory device. The first dielectric layer has a dielectric constant that is less than about 3. The first dielectric layer includes a plurality of metal wires.

In accordance with still another aspect of the present invention, a semiconductor chip is provided, which includes a first voltage source, a second voltage source, a substrate, and a memory device. The first voltage source has a first voltage. The second voltage source has a second voltage. The memory device is in the substrate. A memory cell is in the memory device. The memory cell includes: a first pass gate device and a second pass gate device; a first inverter and a second inverter; a first metal-insulator-metal (MIM) capacitor and a second MIM capacitor, wherein a first electrode of the first MIM capacitor is electrically connected to the first voltage source, wherein a first electrode of the second MIM capacitor is electrically connected to the second voltage source; a first resistor and a second resistor, wherein a first node of the first resistor is electrically connected to an input node of the first inverter, and wherein a first node of the second resistor is electrically connected to an input node of the second inverter; and a first storage node including a source node of the first pass gate device, an output of the second inverter, a second electrode of the first MIM capacitor, and a second node of the first resistor; and a second storage node including a source node of the second pass gate device, an output of the first inverter, a second electrode of the second MIM capacitor, and a second node of the second resistor.

In accordance with yet another aspect of the present invention, a semiconductor chip is provided, which includes a silicon-on-insulator (SOI) substrate, a plurality of transistors, a first dielectric, a second dielectric, and a polyimide layer. The silicon-on-insulator (SOI) substrate includes a first semiconductor layer, a second semiconductor layer, a buried dielectric layer, and a memory device. The first semiconductor layer is proximate a top surface of the SOI substrate. The second semiconductor layer is underlying the first semiconductor layer. The buried dielectric layer is interposed between at least a portion of the first semiconductor layer and the second semiconductor layer. The memory device is in the SOI substrate. The plurality of transistors are overlying the SOI substrate. The first dielectric is overlying the transistors. The second dielectric is overlying the first dielectric. The polyimide layer is overlying the SOI substrate, the transistors, and the second dielectric. A thickness of the polyimide layer is less than about 20 microns.

In accordance with another aspect of the present invention, a dynamic random access memory (DRAM) device is provided, which includes a voltage source, a bit line wire, a substrate, a memory cell, a boron-free inter-layer-dielectric (ILD) layer, and an inter-metal-dielectric (IMD) layer. The voltage source has a substantially time-invariant voltage. The memory cell in the substrate. The memory cell includes a capacitor and a transistor. The capacitor includes a first electrode and a second electrode, wherein the first electrode is electrically connected to the voltage source. The transistor includes a drain node and a source node, wherein the drain node is electrically connected to the second electrode, and the source node is electrically connected to the bit line wire. The boron-free inter-layer-dielectric (ILD) layer is overlying the substrate. The inter-metal-dielectric (IMD) layer has a dielectric constant that is less than about 3. The IMD layer includes a plurality of metal wires.

The foregoing has outlined rather broadly the features and technical advantages of the present invention in order that the detailed description of the invention that follows may be better understood. Additional features and advantages of the invention will be described hereinafter, which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows a layout view of the SRAM device of a first illustrative embodiment of the present invention;

FIG. 2 shows a cross sectional view of the SRAM device of the first illustrative embodiment of the present invention;

FIG. 3a shows a layout view of an SRAM device having more than one NWELL region;

FIG. 3b is a cross-section view of FIG. 3a as taken along line 3b-3b;

FIGS. 4a and 4b show various schematic views of the SRAM cell in the first illustrative embodiment of the present invention;

FIG. 5 shows a schematic view of the SRAM cell with a plan view of selected layout shapes superimposed onto the schematic, in accordance with the first illustrative embodiment of the present invention;

FIG. 6 is a layout view of the SRAM cell of the first illustrative embodiment of the present invention;

FIG. 7 is a three dimensional view of the SRAM cell of the first illustrative embodiment of the present invention;

FIGS. 8 and 9 are cross-sectional views of the SRAM cell of the first illustrative embodiment of the present invention;

FIG. 10 is a cross sectional view of an illustrative embodiment of the present invention;

FIG. 11 is a schematic view of a DRAM cell in accordance with a second illustrative embodiment of the present invention;

FIG. 12 is a cross-sectional view of a DRAM cell in accordance with the second illustrative embodiment of FIG. 11;

FIG. 13 is a schematic view of an SRAM cell in accordance with an illustrative embodiment of the present invention;

FIG. 14 is a schematic view of an SRAM cell in accordance with an illustrative embodiment of the present invention;

FIG. 15 is a schematic view of an SRAM cell in accordance with an illustrative embodiment of the present invention;

FIG. 16 shows a layout view of the SRAM device of a tenth illustrative embodiment of the present invention; and

FIG. 17 shows a cross sectional view of the SRAM device of the tenth illustrative embodiment of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely-illustrative of specific ways to make and use the invention, and do not limit the scope of the invention.

An illustrative embodiment of the present invention provides a high-speed memory device with a low soft error rate (SER). In accordance with a first illustrative embodiment, a high-speed static random access memory (SRAM) device with low soft error rate (SER) is discussed. Regarding the SRAM device of the first embodiment, first it will be described generally while discussing the physical structure of the device. Then, the components of the SRAM device will be described in more detail. Specifically, a six transistor (6T) SRAM cell in the SRAM device of the first embodiment will be discussed. A discussion of the electrical configuration of the 6T SRAM cell will be provided first, followed by a discussion of the physical structure of the 6T SRAM cell.

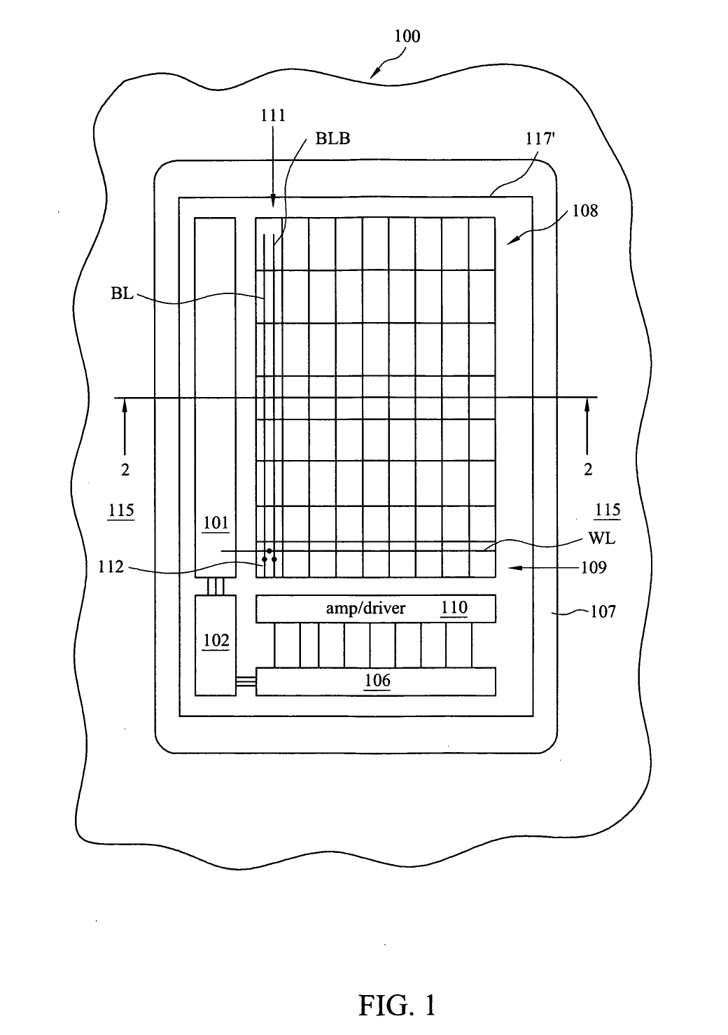

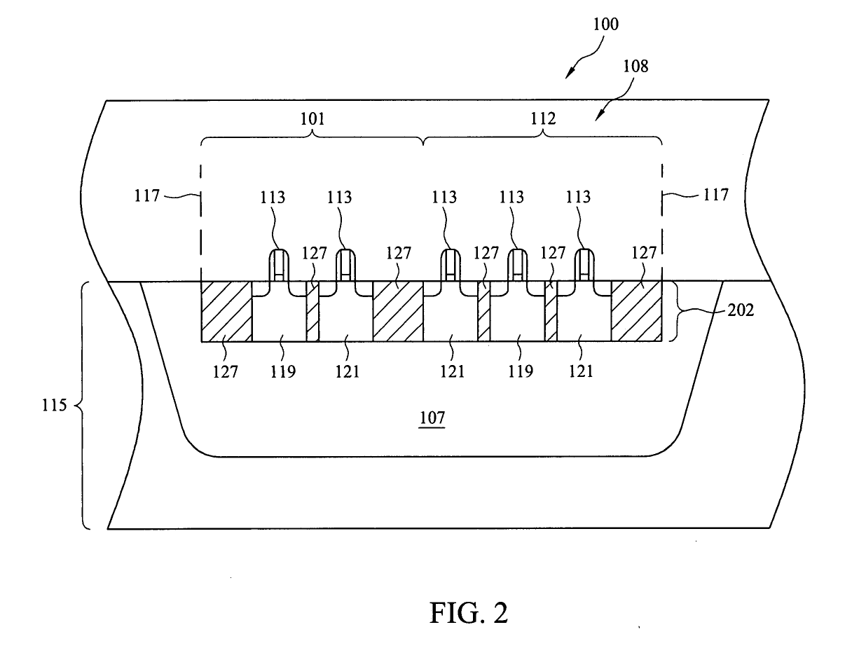

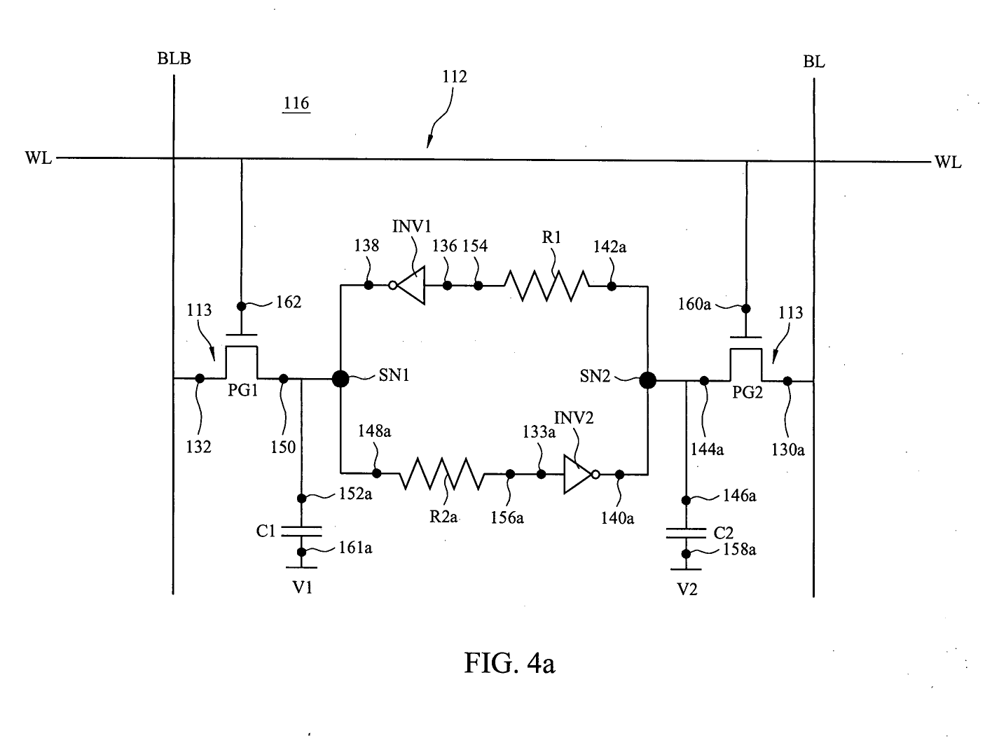

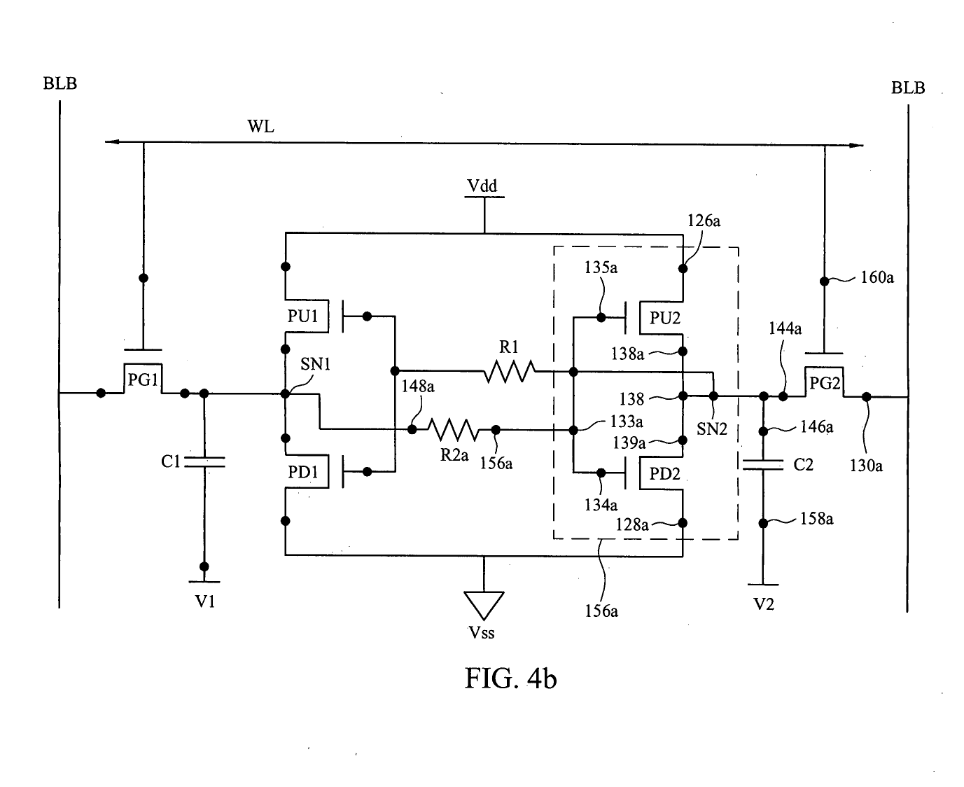

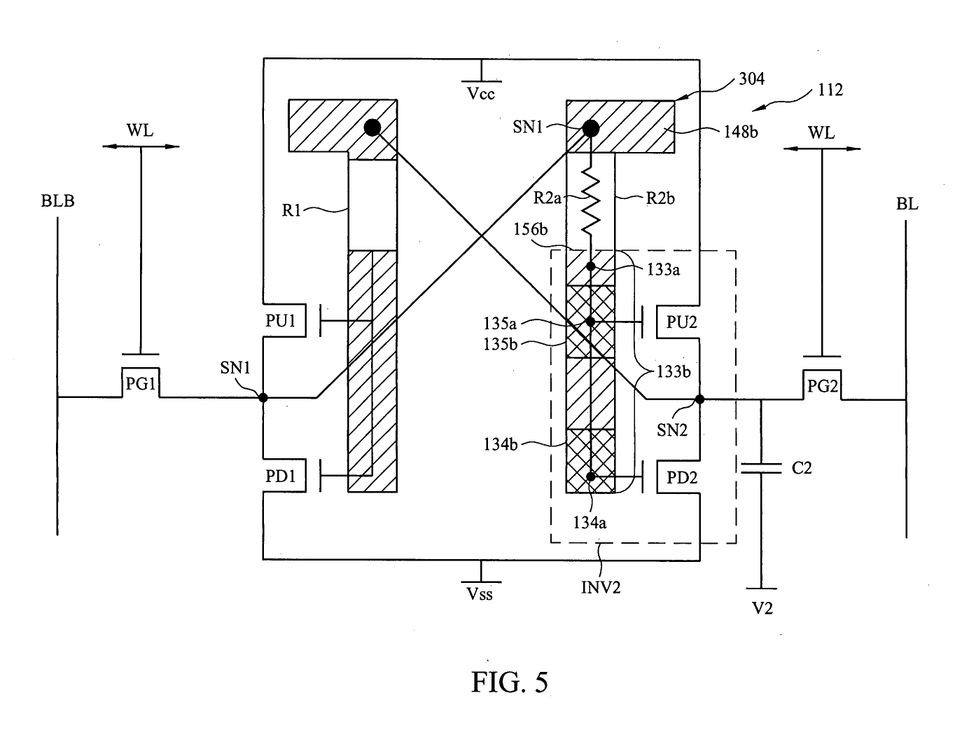

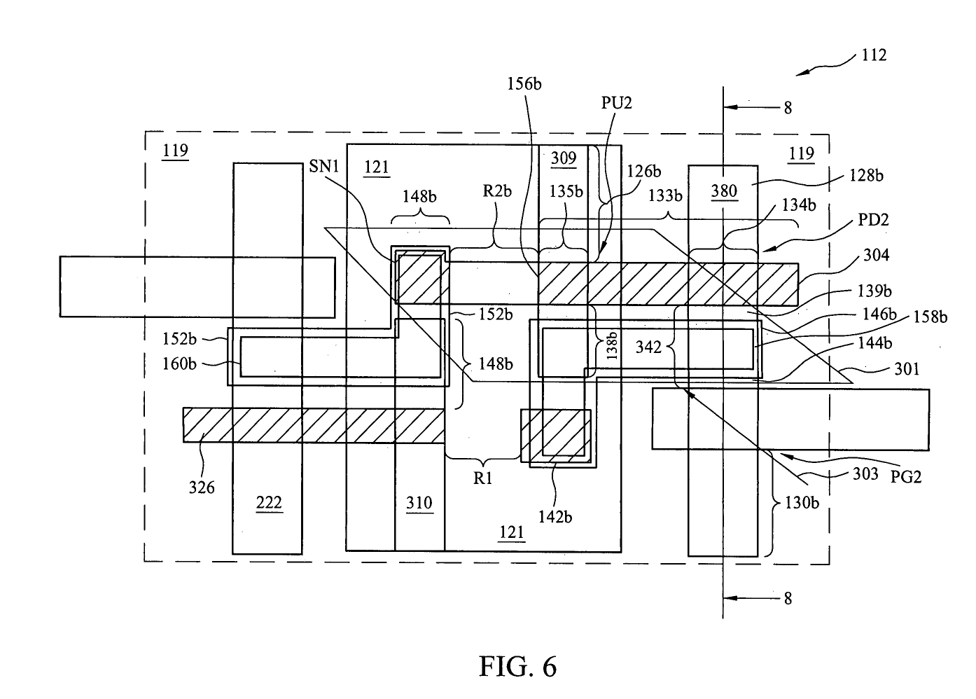

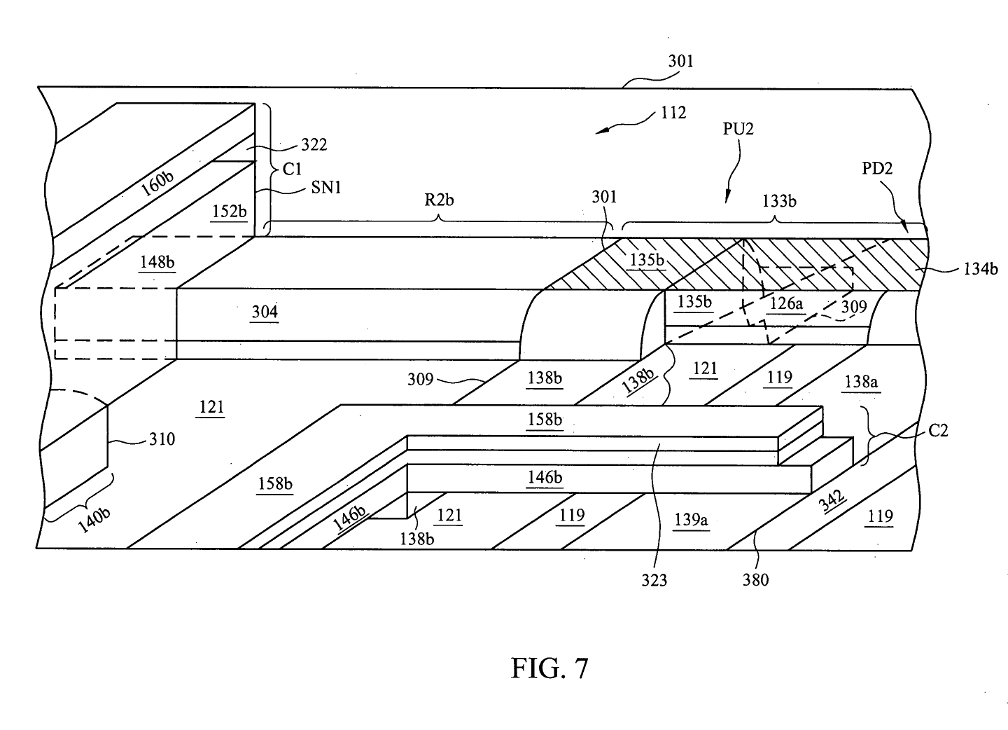

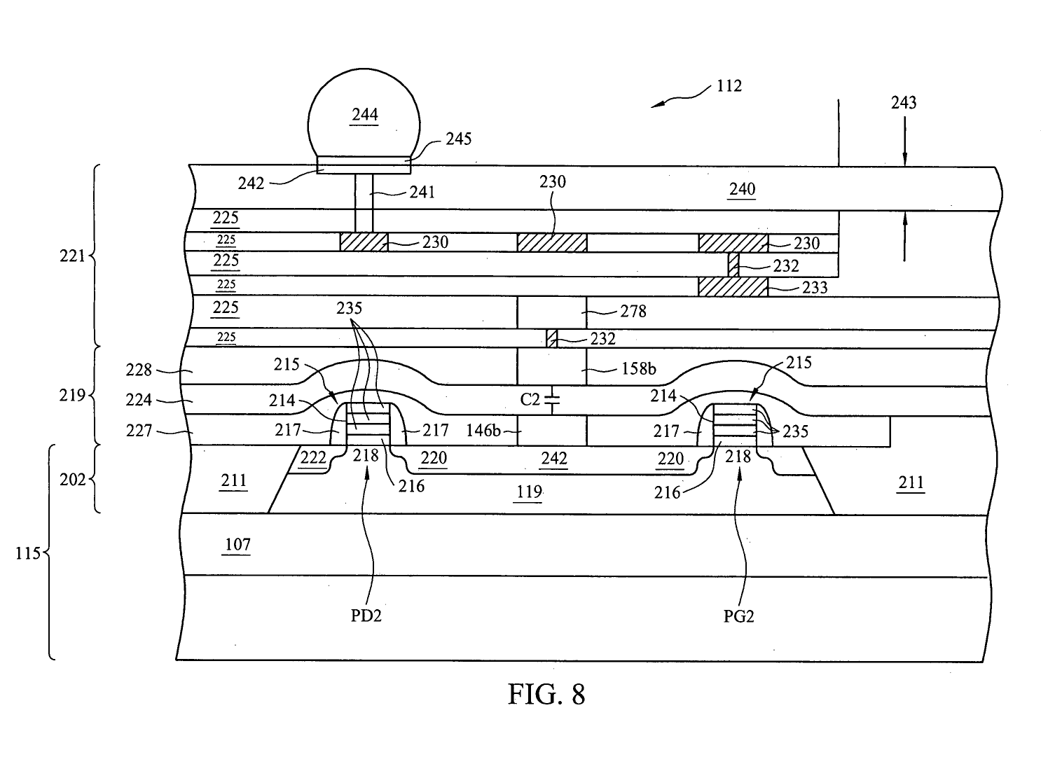

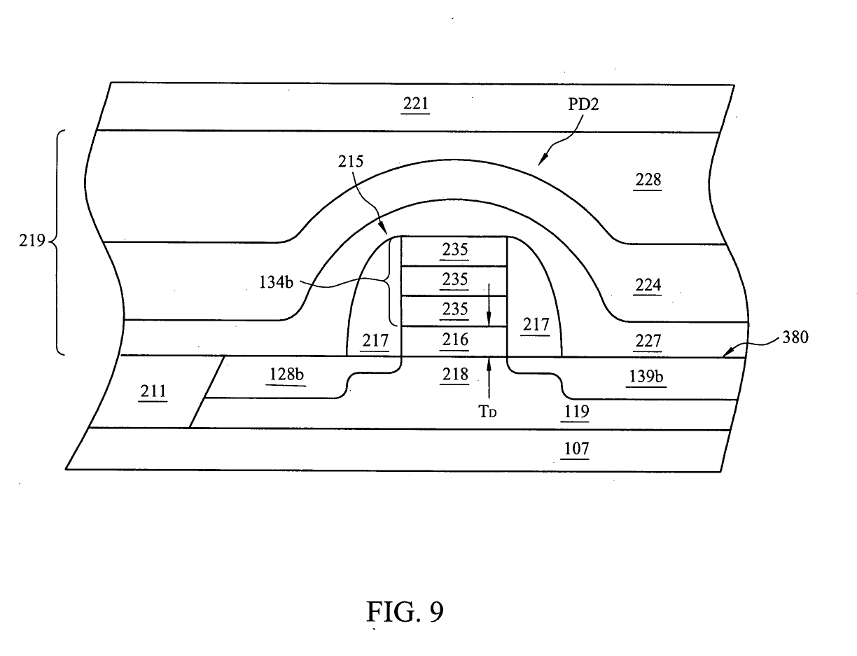

Various views and configurations of the first embodiment are provided below, and shown in FIGS. 1-2, and 4a-9. FIG. 1 shows a layout view of the SRAM device of the first embodiment. FIG. 2 shows a cross sectional view of the SRAM device of the first embodiment. FIGS. 4a-5 are illustrative electrical diagrams of an SRAM cell in the SRAM device of the first embodiment. FIGS. 4a and 4b show various schematic views of the SRAM cell in the first embodiment. To aid in correlating the electrical configuration of the SRAM cell of the first embodiment to a physical structure of the SRAM cell, FIG. 5 shows a schematic view of the SRAM cell with a plan view of selected layout shapes superimposed onto the schematic. FIGS. 6-9 show various views of the physical structure of the SRAM cell of the first embodiment. Thus, FIG. 6 is a layout view of the SRAM cell, FIG. 7 is a three dimensional view of the SRAM cell, and FIGS. 8 and 9 are cross-sectional views of the SRAM cell.

The first illustrative embodiment of the present invention includes an SRAM device 100, as shown in FIG. 1. FIG. 1 shows some of the functional blocks in a system level architecture of the SRAM device 100. Illustrative embodiments may include any memory device having a system architecture similar to the SRAM device 100, such as a dynamic random access memory (DRAM) device, for example.

The SRAM device 100 in FIG. 1 is in a mixed signal chip formed in a deep NWELL region 107 of a substrate 115. Note that the remaining portions of the mixed signal chip are not shown in FIG. 1. The SRAM device 100 may be included in any of a variety of semiconductor chips and semiconductor applications, such as in system on a chip (SoC) applications, memory chip applications (e.g., dual inline memory modules (DIMMs), small outline dual in line memory modules (SoDIMMs), and double data rate (DDR) memories). Memory devices in illustrative embodiments may be formed in any type of wafer. For example, illustrative embodiments include memory devices in silicon on insulator (SOI) wafers, gallium arsenide wafers, in indium phosphate wafers, in bulk silicon wafers, in silicon germanium wafers, in ceramic wafers, and combinations thereof.

The system level architecture of the SRAM device 100 shown in FIG. 1 may be described as follows. The controller 102 operates the column decoder 106, the row decoder 101, and the amp/driver block 110, in order to store binary data to, and read binary data from, the SRAM cells 112. The memory array 108 in FIG. 1 includes SRAM cells 112 arranged in rows 109 and columns 111. Word line wires WL, are electrically connected to rows 109 of the SRAM cells 112. Bit line wires BL and BLB are electrically connected to columns 111 of the SRAM cells 112.

The SRAM device 100 of the first embodiment is shown in FIG. 1 as being in a substrate 115. The SRAM device 100 may typically share the substrate 115 with other semiconductor devices (not shown). Examples of semiconductor devices that may share a substrate with a memory device may include (but are not limited to) power distribution and regulation devices such as bandgaps and regulators, devices for clock generation and distribution such as analog and digital PLLs, CMOS integrated circuits of varying scales of integration (e.g., very large scale integration (VLSI), ultra large scale integration (ULSI)), digital signal processors, microprocessors, and combinations thereof.

FIG. 2 shows a simplified cross sectional view of the SRAM device 100 of the first illustrative embodiment. The cross-sectional view in FIG. 2 corresponds to a portion of the SRAM device 100 along the line 2-2, shown in FIG. 1. The substrate material 115 preferably includes a silicon material, for example.

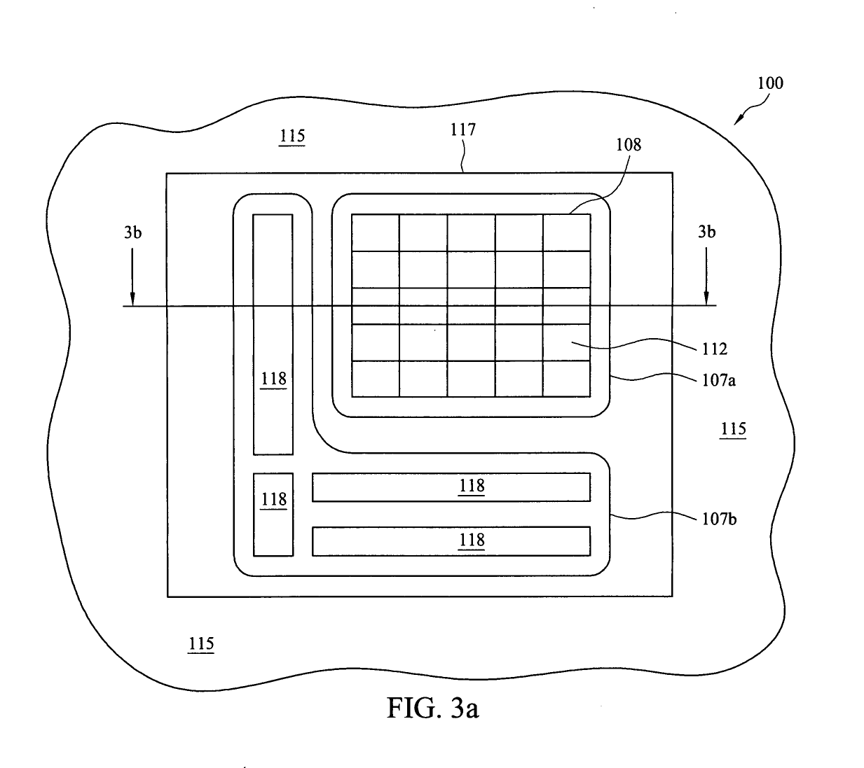

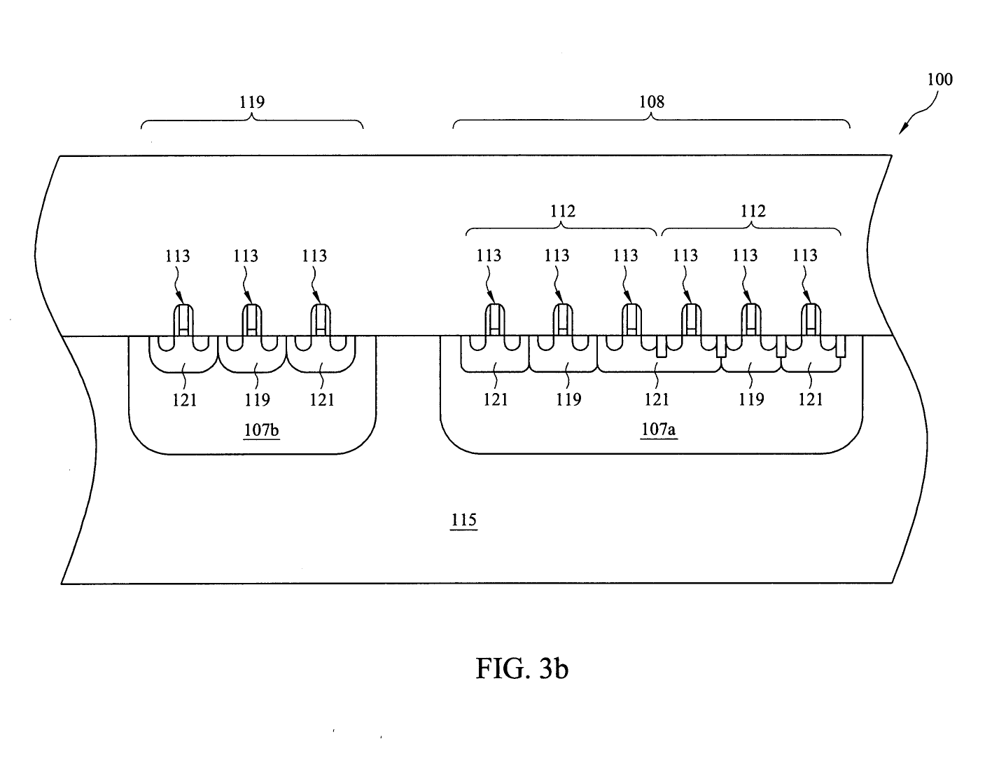

FIGS. 3a and 3b show the views in FIG. 1 and FIG. 2 respectively, for another illustrative embodiment. More specifically, FIGS. 3a and 3b show an illustrative embodiment having more than one deep NWELL region 107. FIG. 3a shows the layout view of an SRAM device 100 with more than one NWELL region 107a, 107b. Referring to FIG. 3a, the SRAM device 100 is in a bulk silicon substrate 125 rather than SOI, for example. The memory array 108 of the SRAM device 100 is surrounded by a first deep NWELL region 107a. The remaining SRAM blocks 118 are surrounded by a second deep NWELL region 107b. FIG. 3b shows a cross section of the SRAM device 100.

The cross-sectional view in FIG. 3b represents the SRAM device 100 of FIG. 3a along the line in 3b-3b. The deep NWELL region 107b is separated from the deep NWELL region 107a. The separated deep NWELL regions 107a and 107b isolate the SRAM cells 112 in the memory array 108 from the transistors 113 in the SRAM block 118, in addition to protecting the SRAM cells 112 in the memory array 108 from substrate noise generated by other semiconductor devices (not shown).

With reference to FIG. 3a, the memory array 108 includes millions of SRAM cells 112. In other illustrative embodiments, the memory arrays may include any number of memory cells capable of storing binary data (e.g., logic ‘0’ or logic ‘1’). Memory arrays in illustrative embodiments may have thousands, billions, or trillions of cells, for example.

Now that the SRAM device 100 of the first embodiment has been described at a device level, the components of the SRAM device 100 of the first embodiment will be discussed in more detail with reference to FIGS. 4a-5. FIGS. 4a-5 are illustrative electrical diagrams of an SRAM cell 112 in the SRAM device 100 of the first embodiment. FIGS. 4a and 4b show various schematic views of the SRAM cell 112 in the first embodiment. FIG. 5 shows a combination of electrical symbols and physical shapes in order to bridge the discussion of the electrical configuration of the SRAM cell 112 of the first embodiment to a discussion of the physical structure of the SRAM cell 112.

The SRAM cell 112 of the first embodiment, shown in FIG. 4a, may be generally referred to as a six-transistor (6T) SRAM cell. Other memory devices in other illustrative embodiments include other types of cells capable of storing one or more charges, including (but not limited to) an eight transistor (8T) SRAM cell, a ten transistor (10T) SRAM cell, a twelve transistor (12T) SRAM cell, CAM cells, and DRAM cells, for example.

One skilled in the art will recognize that illustrative embodiments described herein may be repeated any number of times in the same illustrative embodiment and in other illustrative embodiments. For example, a discussion of the storage node SN2 in FIG. 4a will provide one skilled in the art with sufficient knowledge to repeat the illustrative embodiment for the storage node SN1. It should be noted, however, that illustrative embodiments are not limited to symmetric memory cells, and that the SRAM cell 112 of the first illustrative embodiment is represented as generally symmetric to facilitate discussion.

FIG. 4a shows a schematic view of the SRAM cell 112 of the first embodiment. The SRAM cell 112 in FIG. 4a comprises a capacitor C2 and a resistor R2. The resistor R2 has a node 148a electrically connected to a storage node SN1 and a node 156a electrically connected to an input 133a of an inverter INV2. The capacitor C2 has an electrode 146a electrically connected to a storage node SN2 and another electrode 158a electrically connected to a voltage source (not shown). The voltage source has a substantially constant voltage V2.

Although a constant voltage source may vary slightly with respect to time (e.g., within a margin of 3%, 5%, or 10%), a constant voltage source is generally considered invariant with respect to time. The voltage V2 has a substantially constant voltage amplitude between about Vss (e.g., about zero volts) and about Vdd (e.g., about 1.8 volts, about 1.5 volts, or about 0.8 volts). The voltage V1 may have a voltage similar to the voltage V2, however, in illustrative embodiments, the voltages V1 and V2 may be independent of each. In a typical application, for example, these two voltages (V1 and V2) are almost the same (e.g., Vcc, Vss, a constant voltage).

As shown in FIG. 4a, the source node 130a of the pass gate transistor PG2 is preferably electrically connected to the bit line BL. The source node 132 of the pass gate transistor PG 1 is preferably electrically connected to the bit line BLB. The bit lines BL and BLB are electrically connected to the amp/driver block 110 as shown in FIG. 1.

Continuing with reference to FIG. 4a, the drain node 144a of the pass gate transistor PG2 is electrically connected to the output 140a of the inverter INV2, to the electrode 146a of the capacitor C2, and to the node 142a of the resistor R1. The electrical connection of the nodes 140a, 142a, 144a, and 146a is represented as a storage node SN2. When the word line wire WL has a low voltage (e.g., about zero volts), the gate node 160a of the n-type metal oxide semiconductor (NMOS) pass gate transistor PG2 is substantially shut. Electrical current flow is thereby practically eliminated between the bit line BL and the storage node SN2. In this situation, and provided the pass gate PG1 is performing properly, the storage node SN2 holds an electric charge coterminous with the complement of the charge held in the storage node SN1. For example, if an electric charge representing logic ‘1’ (e.g., Vdd) is held in storage node SN2, an electric charge representing logic ‘0’ (e.g., Vss) is held in the storage node SN1.

FIG. 4b shows another schematic view of the SRAM cell 112 of the first embodiment. The electrical connectivity of the SRAM cell 112 may be viewed in more detail in FIG. 4b. The inverter INV2 in the dashed box INV2 includes a pull up transistor PU2 and a pull down transistor PD2. The gate nodes 134a and 135a of the transistors PD2 and PU2, respectively, are electrically connected to form the input node 133a of the inverter INV2. The drain nodes 138a and 139a of the transistors PU2 and PD2, respectively, are electrically connected to each other to form the output node 138 of the inverter INV2. The source node 126a of the pull up transistor PU2 is electrically connected to a voltage source (not shown), which provides a voltage of about Vdd (e.g., about 1.5 volts, or about 0.8 volts), and the source node 128a of the pull down transistor PD2 is electrically connected to a ground source (not shown) which provides a voltage of about Vss (e.g., about zero volts).

To aid in correlating the electrical configuration of the SRAM cell 112 of the first embodiment to a physical structure of the SRAM cell, FIG. 5 shows a schematic view of the SRAM cell 112 with a plan view of selected layout shapes superimposed onto the schematic. With respect to a physical representation of the first illustrative embodiment, FIG. 5 is a schematic of the SRAM cell 112 that is similar to the schematic 4b. However, FIG. 5 represents the resistor R2a as a layout shape R2b inside a layout shape of a gate electrode 304. The portion R2b of the gate electrode 304 has a high resistance that corresponds to the resistance of the resistor R2a in FIGS. 4a and 4b. The resistor R2a is represented in FIG. 5 in a manner that illustrates the physical placement of the resistor R2a with respect to other devices. In addition to having the resistive portion R2b, the gate electrode 304 includes a contacted region 148b and an inverter input gate node region 133b. The inverter input gate node region includes the input 133a for the inverter INV2. The inverter INV2 is outlined in FIG. 5 with a dashed line. The inverter INV2 includes the pull up transistor PU2 and the pull down transistor PD2.

The contacted portion 148b in FIG. 5 of the gate electrode 304 is electrically connected to the storage node SN1. The gate node portion 133b of the gate electrode 304 is the input node 133a of the inverter INV2. The gate node portion 133b of the gate electrode 304 includes a gate node portion 134b and a gate node portion 135b. The gate node portion 134b of the gate electrode 304 includes the gate node 134a of the pull down transistor PD2. The gate node portion 135b of the gate electrode 304 includes the gate node 135a of the pull down transistor PD2.

The contacted portion 148b of the gate electrode 304 and the inverter input gate node portion 133b of the gate electrode 304 are on oppositely adjacent sides of the resistor portion R2b of the gate electrode 304. The resistor portion R2b of the gate electrode 304 is positioned at the gate end 156b of the gate node portion 134b. The portion R2b of the gate electrode 304 may be highly resistive.

With reference now to FIGS. 6-9, a description of the physical structure of the first illustrative embodiment is included below. FIG. 6 is a layout view of the SRAM cell. FIG. 7 is a three dimensional view of the SRAM cell. FIGS. 8 and 9 are cross-sectional views of the SRAM cell of the first embodiment.

FIG. 6 shows a plan view of the SRAM cell 112. An NWELL region 121 is surrounded by a PWELL region 119. The p-type diffusion region 309 in the NWELL region 121 comprises the pull up transistor PU2. A portion 126b of the p-diffusion region 309 includes the source node 126a of the pull up transistor PU2. Another portion 138b of the p-diffusion region 309 includes the drain node 138a of the pull up transistor PU2.

The PWELL region 119 in FIG. 6 includes an n-type diffusion region 380, which includes the transistors PD2 and PG2. The n-diffusion region 380 also includes a portion 128b, which includes the source node 128a of the pull down transistor PD2, and a portion 139b, which includes the drain node 139a of the pull down transistor PD2. The portion 130b of the n-diffusion region 380 includes the source node 130a of the pass gate transistor PG2, and a portion 144b includes the drain node 144a of the pass gate PG2. The portions 139b and 144b may be collectively referred to as a shared drain diffusion region 342 of the n-diffusion region 380. In the shared drain diffusion region 342, the drain node 139a of the pull down transistor PD2 is electrically connected to the drain node 144a of the pass gate PG2.

The two portions 148b and 133b of the gate electrode 304 in FIG. 6 are silicided and may include materials added to the gate electrode that cause the portions 148b and 133b to have a low resistance. Diagonal lines in FIGS. 5, 6, and 7, which added solely for clarity, highlight the low resistance portions 148b and 133b of the gate electrode 304. The portion 148b of the gate electrode 304 in FIG. 6 is silicided to minimize contact resistance between the gate electrode 304 and a buried wire 152b. In operation, the portion 148b of the gate electrode 304 holds the charge of the storage node SN1. The silicided portion 133b of the gate electrode 304 corresponds to the gate input node 133a of the inverter INV2. A gate end 156b is shown in FIG. 6 interposed between the resistive portion R2b of the gate electrode 304 and the silicided portion 133b of the gate electrode. The gate end 156b represents the resistor node 156a in FIGS. 4a and 4b. The silicided portion 133b of the gate electrode 304 also includes the gate electrode 134b for the pull down transistor PD2, and the gate electrode 135b of the pull up transistor PU2. The resistive portion R2b of the gate electrode 304 is highly resistive (e.g., a sheet resistance in a range of about 100 Ω/μ² to about 10,000 Ω/μ²) to current flow and causes a voltage difference between the portion 148b of the gate electrode 304 having the storage node SN1, and the portion 133b of the gate electrode 304 having the input gate node 133a of the inverter INV2.

A buried wire 146b in FIG. 6 electrically connects the shared drain diffusion region 342, the diffusion region 138b, and a silicided portion 142b of the gate electrode 326, thereby forming the storage node SN2. The buried wire 146b also includes the electrode 146a of the capacitor C2. The electrode 158a is included in a buried wire 158b overlying the buried wire 146b. A capacitor dielectric (not shown) separates the buried wire 146b and the buried wire 158b.

FIG. 7 is a three dimensional view of the SRAM cell of the first illustrative embodiment of the present invention. The three dimensional view in FIG. 7 further illustrates the physical structure of the capacitor C2 and other portions of the SRAM cell 112. The view in FIG. 7 corresponds to the region 301 in FIG. 6 in the direction of sight indicated by the arrow 303. In FIG. 7, a portion 140b of the p-diffusion region 310 is shown in the NWELL region 121. The portion 140b includes the drain node 140a of the pull up transistor PU1 and is shown in the bottom left corner of FIG. 7. The buried wire 152b is shown overlying and contacted to the portion 140b of the p-diffusion region 310. The buried wire 152b, which includes the node SN1, is extended across the PWELL region 121. The buried wire 152b is shown electrically connected with the silicided portion 148b of the gate electrode 304. The buried wire 152b includes the electrode 152a of the capacitor C1.

In the top left corner of FIG. 7, the electrode 160a of the capacitor C1 is also a buried wire 160b overlying the buried wire 152b. A capacitor dielectric material 322 is interposed between the two buried wires 152b and 160b. The resistive portion R2b of the gate electrode 304 lies between the portion 148b of the electrode 304 and the portion 133b that includes the input 133a to the inverter INV2.

The transistor PU2 and a portion of the transistor PD2 are shown in FIG. 7. The p-diffusion region 138b of the diffusion region 309, which includes the drain node 138a of the pull up transistor PU2, is shown electrically connected to the shared diffusion region 342 by the buried wire 146b. The buried wire 146b is shown electrically connected to the shared drain diffusion region 342, and the diffusion region 138b. Although not shown in FIG. 7, the buried wire is also electrically connected to a portion of the gate electrode 326 as shown in the plan view of FIG. 6. The electrical connections of the buried wire 146b form the storage node SN2. The buried wire 146b is also includes the electrode 146a of the capacitor C2. The electrode 158a of the capacitor C2 is a buried wire 158b overlying the buried wire 146b. A capacitor dielectric material 323 is interposed between the two buried wires 146b and 158b.

FIG. 8 is a first cross-sectional view of the SRAM cell 112 of the first embodiment. As shown in FIG. 8, which is a cross sectional view of the layout view in FIG. 6 along the line 8-8, the capacitor C2 is formed in a boron-free inter-layer-dielectric ILD layer 219 and under a plurality of low k dielectric layers 225 of an IMD layer 221. The metal material in the electrodes of the MIM capacitor C2 is preferably copper. The MIM capacitors in other illustrative embodiments may include other suitable metal materials such as aluminum, copper alloys, aluminum alloys, copper aluminum alloys, and combinations thereof, for example.

Advantages are achieved in illustrative embodiments that include capacitors formed in the ILD layer 219. Forming storage node capacitors (e.g., C1 and C2 in illustrative embodiments) in a boron-free ILD layer contributes toward minimizing SRAM manufacturing difficulties that arise from forming storage node capacitors in the IMD layer 221. Although the formation of storage node MIM capacitors in boron-free ILD layer is preferred, embodiments include storage node capacitors having any structure or shape and formed above an ILD layer, for example. For example, in U.S. Pat. No. 6,649,456, entitled “SRAM Cell Design For Soft Error Rate Immunity,” and incorporated by reference herein, various storage node capacitor structures are presented, including storage node capacitors formed in an ILD layer and various capacitor structures formed in an IMD layer.

The transistors PG2 and PD2 in FIG. 8 are in the PWELL 119. The PWELL 119 is in the deep NWELL region 107. The pass gate transistor PG2 and the pull down transistor PD2 are isolated by shallow trench isolation structures 211. An inter-layer-dielectric (ILD) layer 219 in FIG. 8 overlies the transistors PG2 and PD2 in the SRAM cell 112. The ILD layer 219 surrounds the buried wires 158b and 146b that form the capacitor C2.

FIG. 9 is a second cross-sectional view of the SRAM cell 112. FIG. 9 shows an enlarged view of the transistor PD2 of FIG. 8 under the multi-layered ILD layer 219. The transistor PD2 in FIG. 9 is generally representative of the six transistors in the SRAM cell. The transistor PD2 includes the gate structure 215. The gate structure 215 includes a gate dielectric 216 and an overlying gate electrode 214 interposed between a pair of spacers 217. The gate dielectric 216 overlies a channel region 218. The gate electrode 214 of the SRAM transistor PD2 includes multiple conductive layers 235. The layers 235 may comprise different conductive materials, such as tungsten, nickel, polysilicon metal alloys, aluminum, titanium, and combinations thereof. The gate dielectric 216 of the transistor PD2 is preferably less than about 1000 angstroms thick T_{D}. The channel region 218 of the transistor PD2 is directly under the gate dielectric 216 and interposed between the drain region 139b and the source region 128b of the n-diffusion region 380.

The ILD layer 219 in FIG. 9 includes a plurality of layers 224, 227, and 228 having a plurality of dielectric materials. The layer 227 may include Si3N4, SiON, nitrided dielectric, high K dielectric, or combinations thereof, for example. The layer 227 is shown directly overlying the gate structure 215, the active region 218, the source region 128b, and the drain region 139b of the transistor PD2. A major purpose of this layer 227 is as a contact etch stop layer. The layer 224 may include a phosphosilicate glass (PSG) material, for example. The layer 224 is shown directly overlying the layer 227. The layer 228 overlying the PSG layer may comprise other suitable dielectric materials that preferably getter mobile ions in the oxide, or the layer 228 may substantially similar to layer 224, for example. All three layers 224, 227, and 228 are boron-free. Although all materials in the ILD layer 219 are boron-free, illustrative embodiments are not so limited and include ILD layers having materials containing boron.

Referring again to FIG. 8, and with continued reference to the first illustrative embodiment, an inter-metal-dielectric (IMD) layer 221 includes a plurality of metal wires 230 and vias 232 surrounded by a plurality of dielectric layers 225. The metal wires 230 and vias 232 comprise copper and other materials associated with a copper metallization process. The wires 230 and vias 232 in other illustrative embodiments may alternatively include any metal material, including (but not limited to) tungsten, aluminum, aluminum copper, copper, a metal with copper content, a silicide, titanium, TiSi₂, Cobalt, CoSi₂, nickel, NiSi, TiN, TiW, TaN, or combinations thereof, for example.

The dielectric layers 225 in the IMD layer 221 of FIG. 8 preferably include one or more dielectric materials having a dielectric constant (k) value lower than about 3. Dielectric materials in the dielectric layers 225 may include low k dielectric materials such as hafnium oxide, or an air gap structure, for example. Other examples of suitable materials in the MD layer 221 include oxides with carbon content, and porous oxides. The dielectric constant k may also be referred to as relative permittivity, as is well known in the art.

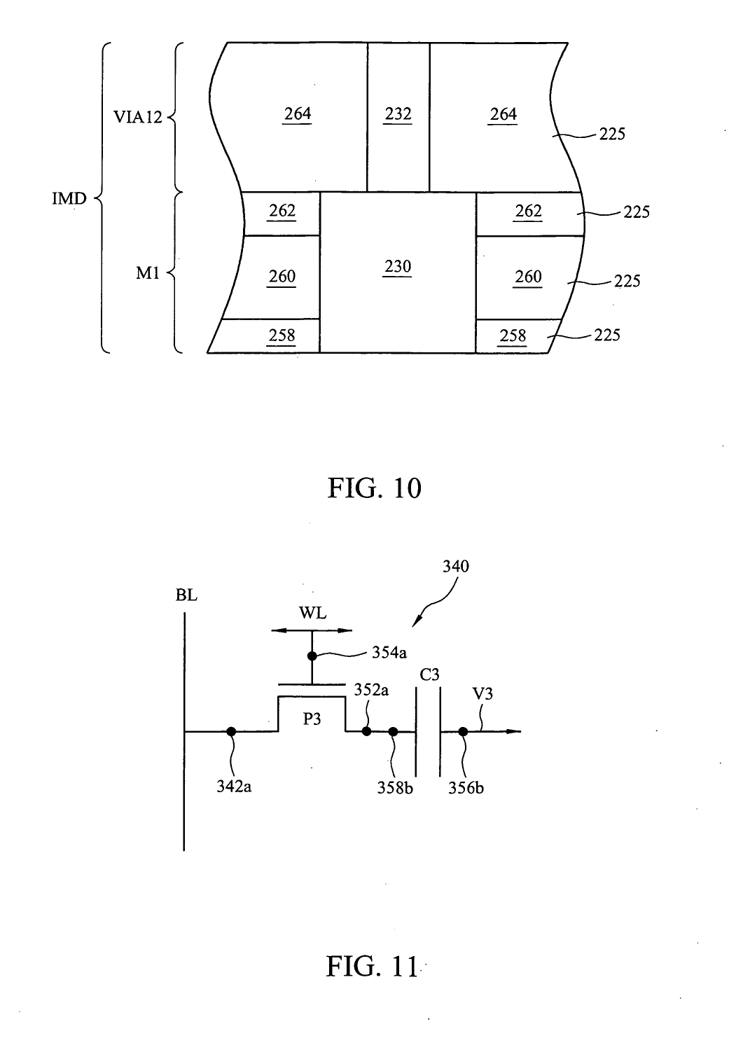

Another illustrative embodiment shown in FIG. 10 shows a via 232 and a metal wire 230 surrounded by dielectric layers 225. The metal 1 layer M1 in the IMD layer shown in FIG. 10 includes the dielectric layers 258, 260, and 262. The via layer VIA12 includes a dielectric layer 264. The layer 258 may include a dielectric material suitable for an etch stop or for a dielectric diffusion barrier layer, for example. The layer 260 may include a low k, or an ultra low k dielectric material. The layer 262 may also be either a dielectric diffusion barrier layer or an etch stop layer, for example. The material of layers 258 and 262 may include Si3N4, SiON and SiC, for example. The dielectric layer 264 may be a low k silicon oxide, for example. Although, the dielectric layers 225 may each have a different dielectric material, the dielectric constant and/or the effective dielectric constant of the layers 225 in the IMD layer 221 are preferably lower than about 3.

With reference to FIG. 8 and to the first illustrative embodiment, a polyimide layer 240 is shown overlying the IMD layer 221. The polyimide layer 240, shown directly overlying the IMD layer 221, is a low stress polyimide. Alternatively, the structure may consist of additional layer(s) imposed between the polyimide 240 and IMD layer 221. Such additional layer(s) may include and un-doped oxide such as un-doped silicate glass (USG) and/or a doped oxide such as fluorosilicate glass (FSG), for example. The polyimide layer 240 has a thickness 243 of preferably less than about 20 microns. The thickness of the polyimide layer 240 may alternatively be less than about 10 microns. The polyimide layer 240 preferably covers the entire SRAM device 100 (See FIG. 1). However, other illustrative embodiments include SRAMs with a polyimide layer overlying a substantial portion of an SRAM device or an SRAM chip, for example. The polyimide layer 240 also includes wiring 241 that electrically connects metal wires 230 in the IMD layer 221 to a pad 242 in the polyimide layer 240. An aluminum layer 245 overlies the bump pad 242. A bump ball 244 is shown electrically connected to the aluminum layer 245. The bump ball 244 and the bump pad 242 do not include any lead material.

The memory device of the first illustrative embodiment and memory devices in other illustrative embodiments include semiconductor devices and materials (e.g., transistors, capacitors, and wires) that are fabricated in a 90 nm generation technology. Other illustrative embodiments may include memory devices formed using semiconductor manufacturing technology from generations larger than 90 nm, and still others may be fabricated using technology from generations smaller than 90 nm, such as technology nodes of 65 nm, 45 nm, and smaller, for example.

Illustrative embodiments may include several advantageous features that provide memory devices with increased soft error rate (SER) immunity and higher operating speeds. For example, electrically connecting a capacitor to each storage node in a memory cell provides additional capacitance to the storage nodes. The capacitance in each storage node provides a constant charging in each storage node, causing each storage node to discharge over a longer period of time. The longer discharging time may significantly decrease the soft error rate (SER).

Another advantageous feature may be the formation of a capacitor in an ILD layer. In previously known methods, capacitors were formed in low k IMD layers. However, forming capacitors in low k IMD layers complicated the fabrication process by creating stress reliability issues during packaging. Storage node capacitors are needed however, in order to improve the SER immunity of memory devices, as described above. Reliability issues during packaging may be significantly reduced by forming capacitors in the ILD layer of memory cells.

Yet another advantageous feature that may be included in illustrative embodiments is the use of low k and ultra low k materials in IMD layers. Using low k dielectric materials to insulate the metal wires in the IMD layer enables faster signal propagation in the metal wires contained therein. As is well known in the art, faster signal propagation enables a memory device to operate at higher speeds.

Still another advantageous feature may include substrate isolation provided by deep NWELL regions, by silicon-on-insulator substrates, and combinations thereof, for example. It is well known in the art that transistors may be protected from substrate noise generated by other devices in the same substrate with a combination of a buried dielectric layer and shallow trench isolation (STI) structures. Placing transistors and semiconductor devices in a deep NWELL region also isolates the transistors from substrate noise. Isolating transistors in an SOI substrate with a deep NWELL region provides more electrical protection than using only an SOI substrate or only a deep NWELL region, but an NWELL region is not required for an SOI substrate.

Another advantageous feature in illustrative embodiments may include overlying an IMD layer with a polyimide layer that has a thickness that is less than about 20 microns and which is alternatively less than about 10 microns. It may be advantageous to have a thin polyimide layer to improve reliability, as a thicker polyimide may impose a higher stress on a low-k IMD layer.

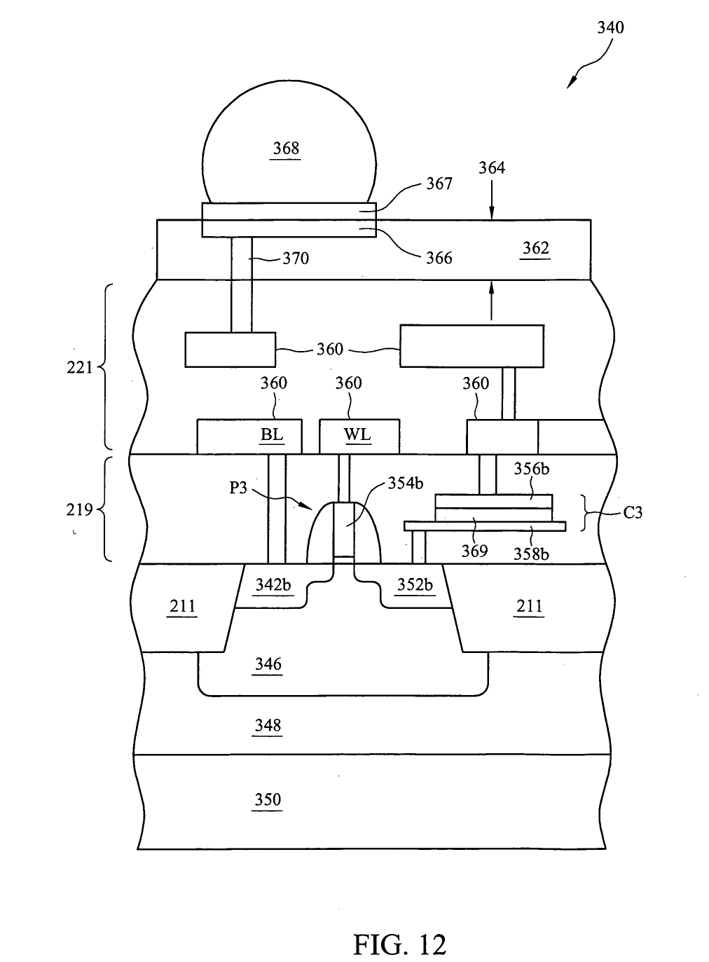

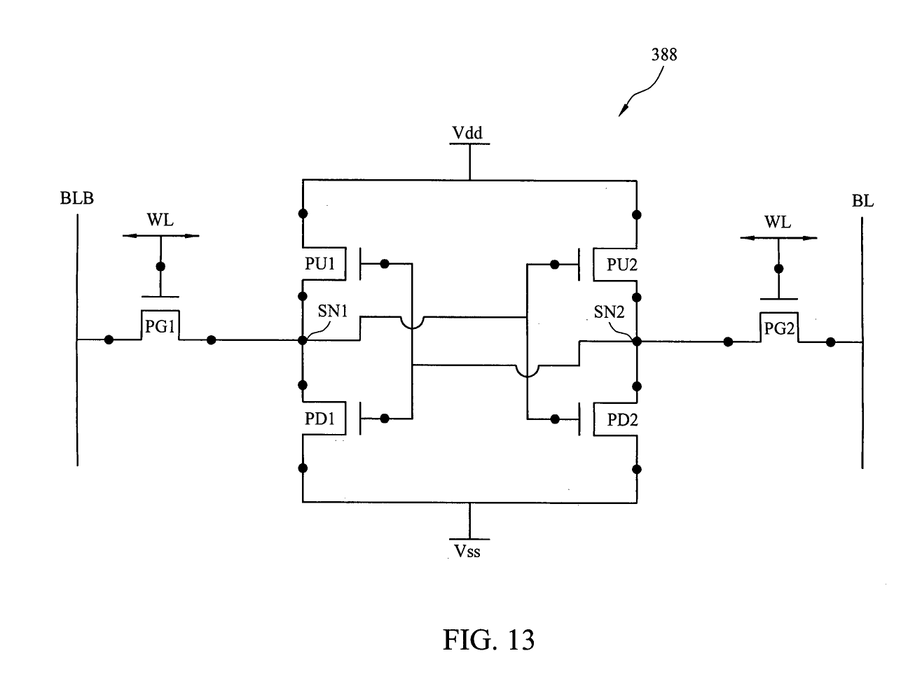

FIGS. 11 and 12 illustrate various views of a second illustrative embodiment. The second illustrative embodiment is a dynamic random access memory (DRAM) device with an array of DRAM cells. FIG. 11 illustrates a schematic view of the DRAM cell 340 of the second embodiment. FIG. 12 illustrates a cross-sectional view of the DRAM cell 340 in accordance with the second illustrative embodiment.

FIG. 11 illustrates the schematic view of the DRAM cell 340 of the second embodiment. The DRAM cell 340 is in a memory array of a DRAM device. Note that the remainder of the memory array and the DRAM device are not shown in FIG. 11. The DRAM device may be a DRAM circuit in a system on a chip (SoC), or it may be part of a memory chip, for example. The DRAM cell 340 has a pass gate device P3 with a drain node 342a electrically coupled to the bit line BL. The source node 352a of the transistor P3 is electrically connected to the capacitor C3 as shown. The capacitor C3 is also electrically connected to a constant voltage source (not shown), which supplies a substantially constant voltage V3 during device operation.

A cross-sectional view of the DRAM cell 340 of the second embodiment is shown in FIG. 12. The DRAM cell may include the pass gate transistor P3 in a PWELL 346. The PWELL 346 is surrounded with a deep NWELL region 348. The NWELL region 348 is in a bulk silicon substrate 350.

The transistor P3 in FIG. 12 of the second embodiment has an n-type diffusion region 342b, which may include the drain node 342a. The n-diffusion region 342b is shown contacted and electrically connected to the bit line wire BL. The transistor P3 also has an n-type diffusion region 352b, which may include the source node 352a. The n-diffusion region 352b is shown contacted and electrically connected to the MIM capacitor C3.

The transistor P3 in FIG. 12 may include a gate electrode 354b electrically connected to the word line wire WL. The MIM capacitor C3 is formed in the boron-free ILD layer 219. The capacitor C3 has a top plate 356b, a bottom plate 358b, and a dielectric material 369 interposed between the two plates. The IMD layer 221 may include one or more dielectric materials surrounding a plurality of metal wires 360. A layer of polyimide 362 overlies the entire DRAM device. Alternatively, the polyimide layer 362 overlays portions of the DRAM device or substantially the entire DRAM device, for example. The polyimide layer 362 has a thickness 364 that is less than about 20 microns. The polyimide layer 362 may alternatively have a thickness 364 less than about 10 microns. The polyimide layer 362 may include copper or aluminum wires 370, for example. The polyimide layer 362 may further include a bump pad 366 having a layer of aluminum material 367 directly overlying the bump pad 366. A bump ball 368 is electrically connected to the aluminum layer 367.

In a third illustrative embodiment of the present invention, a semiconductor chip comprises a logic device. A logic device may include any type of functional circuitry having complimentary metal oxide semiconductor (CMOS) transistors. The logic device may be any type of semiconductor device that uses or has memory devices, for example. Examples of logic devices may include (but are not limited to) digital signal processors, micro controllers, microprocessors, and application specific integrated circuits, for example. Although logic devices comprise any type of semiconductor device, logic devices may include a large number of digital cells such as inverters, NANDs, NORs, flip flops, latches, and buffers, for example.

The logic device of the third illustrative embodiment is in a portion of a substrate surrounded by a deep NWELL. The deep NWELL portion of the third embodiment may be the same as that shown for the first embodiment (See e.g., FIGS. 1-2). A boron-free WLD layer overlies transistors in the logic device. An IMD layer overlying the ILD layer may include a dielectric material with a dielectric constant k of less than about three. The dielectric materials in the IMD layer surround metal wires and vias. The ILD layer and the IMD layer of the third illustrative embodiment may be the same as that shown for the first embodiment (See e.g., FIG. 8).

A polyimide layer overlies the IMD layer. The polyimide layer preferably has a thickness of less than about 20 microns, however, the thickness of the polyimide layer may also be less than about 10 microns, for example. The polyimide layer may include a bump pad directly underlying an aluminum layer. A bump ball is electrically connected to the aluminum layer. The bump ball and the pad are both lead free. The polyimide layer of the third illustrative embodiment may be the same as that shown for the first embodiment (See e.g., FIG. 8).

The logic device of the third embodiment may include semiconductor devices and materials (e.g., transistors, capacitors, and interconnecting wires) that are formed using a 90 nm generation. Other illustrative embodiments are formed using semiconductor manufacturing technology generations of 65 nm, 45 nm, and smaller generations, for example.

A fourth illustrative embodiment of the present invention includes a memory chip. An SRAM device is in a deep NWELL region of a bulk silicon substrate of the memory chip. The SRAM device includes an array of SRAM cells. The SRAM device, the deep NWELL region, and the array of SRAM cells of the fourth illustrative embodiment may be the same as that shown for the first embodiment (See e.g., FIGS. 1-2). Each SRAM cell in the fourth illustrative embodiment is similar to the SRAM cell 388 shown in the schematic of FIG. 13. The SRAM cell 388 includes storage nodes SN1 and SN2, pass gate devices PG1 and PG2, pull up transistors PU1 and PU2, and pull down transistors PD1 and PD2.

With reference to the remaining description of the fourth illustrative embodiment below, portions of the fourth embodiment that are similar to the second embodiment may be the same as that shown for the second embodiment (See e.g., FIG. 12). The SRAM device of the fourth illustrative embodiment is in a substrate. A boron-free ILD layer overlying the substrate has a plurality of boron-free dielectric materials. An IMD layer in the fourth embodiment overlies the ILD layer and includes dielectric materials with a dielectric constant less than about three. A polyimide material overlies the IMD layer. The polyimide material is less than about 20 microns thick, and is alternatively less than about 10 microns thick. The polyimide material further includes a bump pad having a layer of aluminum material directly overlying the bump pad. A bump ball is electrically connected to the aluminum layer. The bump pad and the bump ball are lead free.

In a fifth illustrative embodiment of the present invention, a semiconductor chip includes an SRAM device in a silicon substrate. A deep NWELL region surrounds the SRAM device. The SRAM device is in a deep NWELL portion of the substrate of the memory chip. The SRAM device portion and the deep NWELL region portion of the fifth illustrative embodiment may be the same as that shown for the first embodiment (See e.g., FIGS. 1-2). A boron-free ILD layer in the fifth embodiment overlies the substrate. An IMD layer overlying the ILD layer includes a dielectric material with a dielectric constant less than about three. A polyimide material overlies the IMD layer. The polyimide material is less than about 20 microns thick, and is alternatively less than about 10 microns thick. The boron-free ILD layer portion, the IMD layer portion, and the polyimide layer portion of the fifth illustrative embodiment may be the same as that shown for the first embodiment (See e.g., FIG. 8).

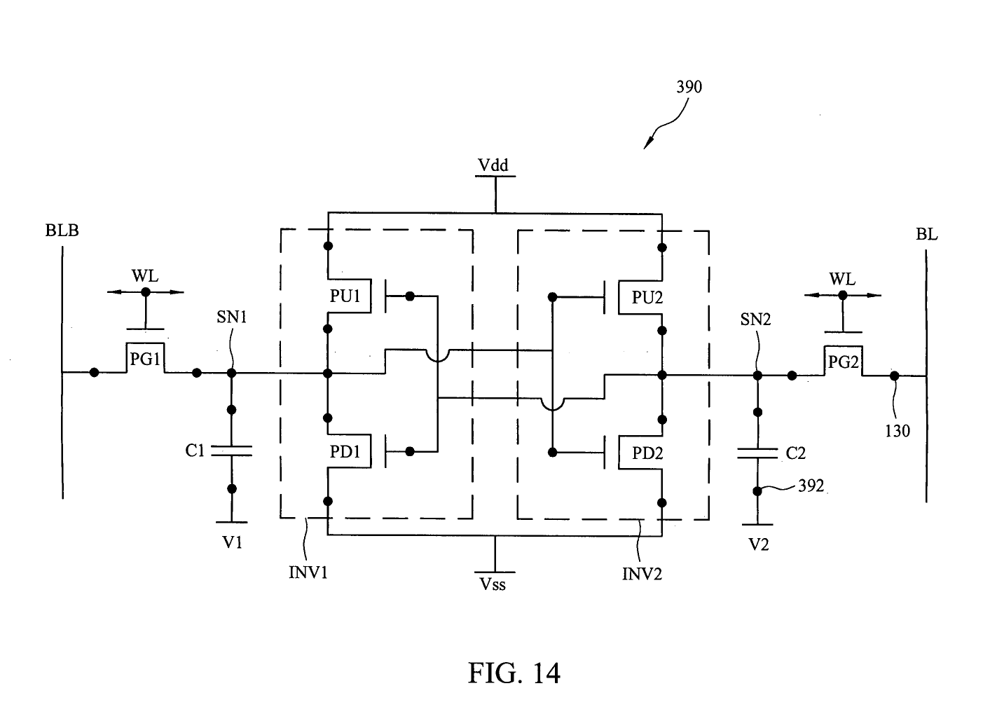

The SRAM device in the fifth illustrative embodiment of the present invention includes an SRAM cell 390, shown in FIG. 14. The SRAM cell 390 includes storage nodes SN1 and SN2, pass gate devices PG1 and PG2, inverters INV1 and INV2, and metal-insulator-metal (MIM) capacitors C1 and C2. The MIM capacitors C1 and C2 are electrically connected to the storage nodes SN1 and SN2, respectively. The capacitor node 392 of the capacitor C2 is electrically connected to a voltage source (not shown), which provides a voltage V2.

In a sixth illustrative embodiment of the present invention, a memory chip includes an SRAM device in a silicon substrate. The SRAM device is in a deep NWELL region of the silicon substrate. The deep NWELL region portion of the sixth illustrative embodiment may be the same as that shown for the first embodiment (See e.g., FIGS. 1-2). A boron-free ILD layer overlies the substrate, insulating the semiconductor devices in the SRAM device. An IMD layer overlying the ILD layer includes a dielectric material with a dielectric constant less than about three. A polyimide material overlies the IMD layer. The polyimide material is less than about 20 microns thick, and is alternatively less than about 10 microns thick. The boron-free ILD layer portion, the IMD layer portion, and the polyimide layer portion of the sixth illustrative embodiment may be the same as that shown for the first embodiment (See e.g., FIG. 8).

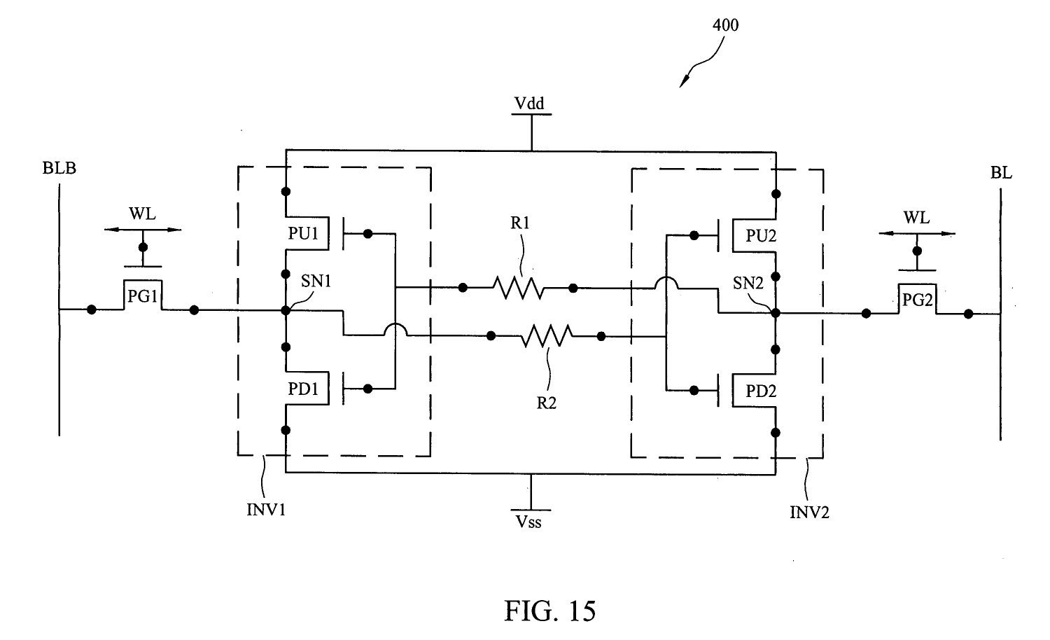

The SRAM device of the sixth illustrative embodiment includes a six-transistor (6T) SRAM cell 400, as shown in FIG. 15. The 6T SRAM cell 400 includes storage nodes SN1 and SN2, pass gate transistors PG1 and PG2, inverters INV1 and INV2, and high resistors R1 and R2. The following description of the resistors R1 and R2, and the inverters INV1 and INV2, may be similar to that shown for the first illustrative embodiment in FIGS. 6 and 7. The high resistors R1 and R2 are electrically connected to the storage nodes SN2 and SN1, respectively. A non-silicided portion of the gate electrode of the inverter INV1 includes the resistor R1. Current flows through the resistor R1 between the storage node SN2 and the input of the inverter INV1. A non-silicided portion of the gate electrode of the inverter INV2 includes the resistor R2. Current flows through the resistor R2 between the storage node SN1 and the input of the inverter INV2.

A seventh illustrative embodiment of the present invention includes an SRAM chip having an SRAM device. The SRAM device includes an array of SRAM cells. The SRAM device, and the array of memory cells may be the same as that shown for the first embodiment (See e.g., FIGS. 1-2). The SRAM cells of the seventh illustrative embodiment may be similar to that shown for the first illustrative embodiment in FIGS. 4a-7. The SRAM cell of the seventh illustrative embodiment includes storage nodes SN1 and SN2, pass gate devices PG1 and PG2, inverters INV1 and INV2, MIM capacitors C1 and C2, and resistors R1 and R2.

The SRAM device in the seventh illustrative embodiment is in a deep NWELL portion of a substrate in an SRAM chip. A boron-free ILD layer overlies the substrate, insulating the semiconductor devices in the SRAM device. An IMD layer overlying the ILD layer includes a dielectric material with a dielectric constant less than about three. A polyimide material overlies the IMD layer. The polyimide material is less than about 20 microns thick, and is alternatively less than about 10 microns thick. The deep NWELL region, the boron-free ILD layer, the IMD layer, and the polyimide layer may all be the same as that shown for the first embodiment (See e.g., FIG. 8).

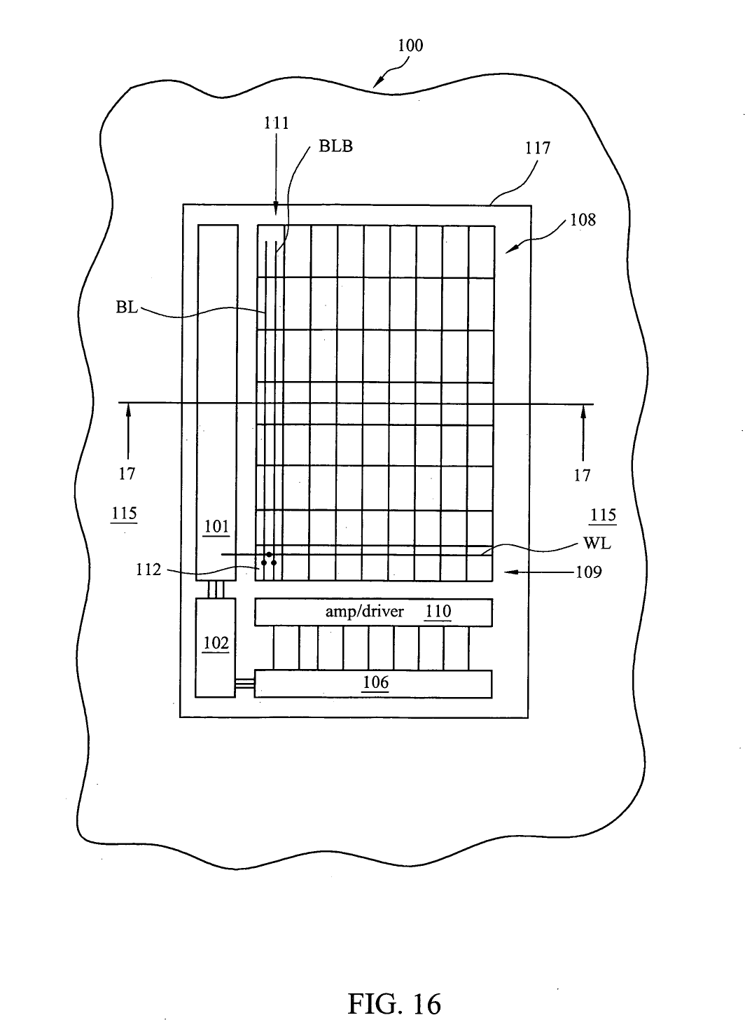

The SRAM device 100 of an eighth embodiment is shown in FIG. 16 as being in a silicon on insulator (SOI) substrate 115. The SRAM device 100 may typically share the SOI substrate 115 with other semiconductor devices (not shown). Examples of semiconductor devices that may share a substrate with a memory device may include (but are not limited to) power distribution and regulation devices such as bandgaps and regulators, devices for clock generation and distribution such as analog and digital PLLs, CMOS integrated circuits of varying scales of integration (e.g., very large scale integration (VLSI), ultra large scale integration (ULSI)), digital signal processors, microprocessors, and combinations thereof.

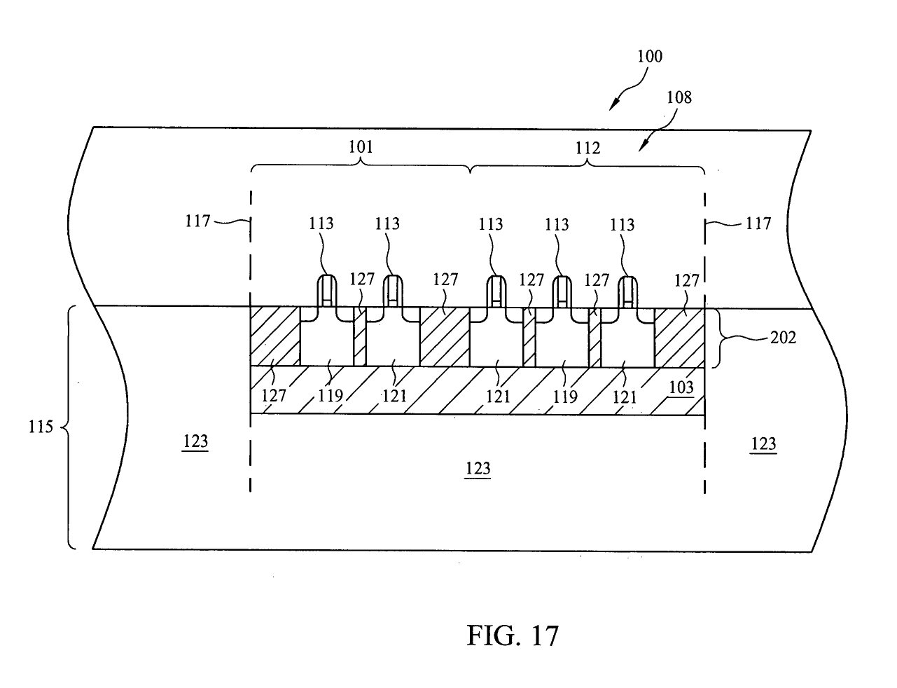

FIG. 17 shows a simplified cross sectional view of the SRAM device 100 of the eighth illustrative embodiment. The cross-sectional view in FIG. 17 corresponds to a portion of the SRAM device 100 along the line 17-17, shown in FIG. 16.

FIG. 17 shows how the buried dielectric layer 103 is in portions of the SOI substrate 115 underlying the SRAM device 100 of the first embodiment. The SOI substrate 115 in FIG. 17 includes a buried dielectric layer 103 interposed between a semiconductor layer 202 and a substrate material 123. The substrate material 123 and the semiconductor layer 202 preferably include a silicon material. The buried dielectric layer 103 may alternatively be formed in any portion of the substrate 115, including being a contiguous layer underlying a substantial portion of the die in which the SRAM device 100 resides. The buried dielectric layer 103 preferably comprises a silicon oxide. Other illustrative embodiments having a buried dielectric layer may include a buried dielectric layer having other materials such as a nitrided oxide or a hydrogenated oxide composite of silicon dioxide, for example.

The SRAM device 100 in FIG. 16 is in a mixed signal chip formed in a silicon on insulator (SOI) wafer 115. Note that the remaining portions of the mixed signal chip are not shown in FIG. 16. The SRAM device 100 may be included in any of a variety of semiconductor chips and semiconductor applications, such as in system on a chip (SoC) applications, memory chip applications (e.g., dual inline memory modules (DIMMs), small outline dual in line memory modules (SoDIMMs), and double data rate (DDR) memories). Memory devices in illustrative embodiments may be formed in any type of wafer. For example, illustrative embodiments include memory devices in gallium arsenide wafers, in indium phosphate wafers, in bulk silicon wafers, in silicon germanium wafers, in ceramic wafers, and combinations thereof.

The system level architecture of the SRAM device 100 shown in FIG. 16 may be described as follows. The controller 102 operates the column decoder 106, the row decoder 101, and the amp/driver block 110, in order to store binary data to, and read binary data from, the SRAM cells 112. The memory array 108 in FIG. 16 includes SRAM cells 112 arranged in rows 109 and columns 111. Word line wires WL, are electrically connected to rows 109 of the SRAM cells 112. Bit line wires BL and BLB are electrically connected to columns 111 of the SRAM cells 112.

In a ninth illustrative embodiment of the present invention, a semiconductor chip includes an SRAM device in a silicon-on-insulator (SOI) substrate. The SOI substrate includes a buried oxide layer interposed between an underlying silicon substrate and an overlying silicon layer. The SOI substrate portion of the ninth illustrative embodiment may be the same as that shown for the eighth embodiment (See e.g., FIGS. 16-17). A boron-free ILD layer overlies the SOI substrate, insulating the semiconductor devices in the SRAM device. An IMD layer overlying the ILD layer includes a dielectric material with a dielectric constant less than about three. The boron-free ILD layer, the IMD layer of the ninth illustrative embodiment may be the same as that shown for the first embodiment (See e.g., FIG. 8). A polyimide material overlies the IMD layer. The polyimide material is less than about 20 microns thick, and is alternatively less than about 10 microns thick. The polyimide material of the ninth illustrative embodiment may be the same as that shown for the polyimide layer in the first embodiment (See e.g., FIG. 8).

The SRAM device of the ninth embodiment includes an SRAM cell 390 shown in FIG. 14. The SRAM cell 390 includes storage nodes SN1 and SN2, pass gate devices PG1 and PG2, inverters INV1 and INV2, and metal-insulator-metal (MIM) capacitors C1 and C2. The MIM capacitors C1 and C2 are electrically connected to the storage nodes SN1 and SN2, respectively. The capacitor node 392 is electrically connected to a voltage source (not shown), which provides a voltage V2. A second node of the MIM capacitor C1 is electrically connected a voltage source (not shown), which has a voltage V1.

In a tenth illustrative embodiment of the present invention, a memory device is in a silicon-on-insulator (SOI) wafer. The SOI substrate of the tenth illustrative embodiment may be the same as that shown for the eighth embodiment (See e.g., FIGS. 16-17) A polyimide material in the tenth illustrative embodiment preferably overlies the memory device and alternatively may overly portions of the SRAM device. The polyimide material is less than about 20 microns thick, and is alternatively less than about 10 microns thick. The polyimide material portion of the tenth illustrative embodiment may be the same as that shown for the polyimide layer in the first embodiment (See e.g., FIG. 8).

Although the present invention and its advantages have been described in detail, it should be understood that various changes, substitutions and alterations can be made herein without departing from the spirit and scope of the invention as defined by the appended claims. As another example, it will be readily understood by those skilled in the art that an SER immune cell structure may be varied while remaining within the scope of the present invention. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A semiconductor chip comprising:
a substrate;
a first dielectric layer overlying said substrate, wherein said first dielectric layer has a dielectric constant that is less than about 3, wherein said first dielectric layer [comprises] includes a plurality of metal wires there within; and
a polyimide layer overlying said first dielectric layer, wherein a thickness of said polyimide layer is less than about 20 microns.

2. The semiconductor chip of claim 1, wherein said substrate comprises a deep NWELL region.

3. A semiconductor chip comprising:
a substrate;
a deep NWELL region in said substrate;
a logic device in said deep NWELL region;
a first dielectric layer overlying said logic device, wherein said first dielectric layer has a diclectric constant that is less than about 3, wherein said first dielectric layer includes a plurality of metal wires there within; and
a polyimide layer overlying said first dielectric layer, wherein a thickness of said polyimide layer is less than about 20 microns.

4. The semiconductor chip of claim 3, further comprising:
a bump pad in said polyimide layer;
an aluminum layer overlying said bump pad; and
a bump ball electrically connected to said aluminum layer.

5. The semiconductor chip of claim 4, wherein said bump pad comprises lead-free materials.

6. The semiconductor chip of claim 4, wherein said bump ball comprises lead-free materials.

7. The semiconductor chip of claim 3, further comprising a boron-free inter-layer-dielectric layer interposed between said substrate and said first dielectric layer.

8. The semiconductor chip of claim 3, further comprising an un-doped oxide interposed between said first dielectric and said polyimide.

9. A static random access memory (SRAM) chip comprising:
a substrate;
a deep NWELL region in said substrate;
an SRAM device in said deep NWELL region;
a first dielectric layer overlying said substrate, wherein said first dielectric layer has a dielectric constant that is less than about 3, and wherein said first dielectric layer comprises a plurality of metal wires; and
a polyimide layer overlying said first dielectric layer, wherein a thickness of said polyimide layer is less than about 20 microns.

10. The SRAM chip of claim 9, further comprising an un-doped oxide interposed between said first dielectric and said polyimide.

11. The SRAM chip of claim 9, further comprising:
a bump pad in said polyimide layer;
an aluminum layer overlying said bump pad; and
a bump ball electrically connected to said aluminum layer.

12. The SRAM chip of claim 11, wherein said bump pad comprises lead-free materials.

13. The SRAM chip of claim 9, wherein said bump ball comprises lead-free materials.

14. The SRAM chip of claim 9, further comprising a boron-free inter-layer-dielectric layer interposed between said substrate and said first dielectric layer.

15. A semiconductor chip comprising:
a substrate;
a memory device in said substrate;
a memory cell in said memory device, said memory cell comprising
a first pass gate device and a second pass gate device,
a first inverter and a second inverter,
a first metal-insulator-metal (MIM) capacitor and a second MIM capacitor, wherein a first electrode of said first MIM capacitor has a first constant voltage, and wherein a first electrode of said second MIM capacitor has a second constant voltage,
a first storage node, wherein said first storage node comprises a source node of said first pass gate device, an output of said second inverter, and a second electrode of said first MIM capacitor, and
a second storage node, wherein said second storage node comprises a source node of said second pass gate device, an output of said first inverter, and a second electrode of said second MIM capacitor; and
a first dielectric layer overlying said memory device, wherein said first dielectric layer has a dielectric constant that is less than about 3.

16. The semiconductor chip of claim 15, wherein a deep NWELL region surrounds said memory device.

17. The semiconductor chip of claim 15, further comprising a polyimide layer overlying said first dielectric layer, wherein said polyimide layer has a thickness less than about 20 microns.

18. The semiconductor chip of claim 17, wherein said thickness of said polyimide layer is about 5 microns.

19. The semiconductor chip of claim 15, further comprising a boron-free dielectric layer interposed between said substrate and said first dielectric layer.

20. The semiconductor chip of claim 19, wherein said boron-free dielectric layer comprises a plurality of boron-free dielectric materials.

21. The semiconductor chip of claim 15, wherein said substrate is a silicon-on-insulator (SOI) substrate comprising:
a first semiconductor layer proximate a top surface of said SOI substrate;
a second semiconductor layer underlying said first semiconductor layer; and
a buried dielectric layer interposed between at least a portion of said first semiconductor layer and said second semiconductor layer.

22. The semiconductor chip of claim 15, wherein said MIM capacitor is under said first dielectric layer.

23. A semiconductor chip comprising:
a substrate;
a memory device in said substrate;
a memory cell in said memory device, said memory cell comprising
a first pass gate device and a second pass gate device,
a first inverter and a second inverter,
a first resistor and a second resistor, wherein a first node of said first resistor is electrically connected to an input of said first inverter, and wherein a first node of said second resistor is electrically connected to an input of said second inverter,
a first storage node comprising a drain node of said first pass gate device, an output of said second inverter, and a second node of said first resistor, and
a second storage node comprising a drain node of said second pass gate device, an output of said first inverter, and a first node of said second resistor; and
a first dielectric layer overlying said memory device, wherein said first dielectric layer has a dielectric constant that is less than about 3, and wherein said first dielectric layer include a plurality of metal wires there within.

24. The semiconductor chip of claim 23, wherein a deep NWELL region surrounds said memory device.

25. The semiconductor chip of claim 23, further comprising a polyimide layer overlying said first dielectric layer, wherein said polyimide layer has a thickness less than about 20 microns.

26. The semiconductor chip of claim 25, wherein said thickness of said polyimide layer is about 5 microns.

27. The semiconductor chip of claim 23, further comprising a boron-free dielectric layer interposed between said substrate and said first dielectric layer.

28. A semiconductor chip comprising:
a first voltage source having a first voltage;
a second voltage source having a second voltage;
a substrate;
a memory device in said substrate; and
a memory cell in said memory device, said memory cell comprising
a first pass gate device and a second pass gate device,
a first inverter and a second inverter,
a first metal-insulator-metal (MIM) capacitor and a second MIM capacitor, wherein a first electrode of said first MIM capacitor is electrically connected to said first voltage source, wherein a first electrode of said second MIM capacitor is electrically connected to said second voltage source,
a first resistor and a second resistor, wherein a first node of said first resistor is electrically connected to an input node of said first inverter, and wherein a first node of said second resistor is electrically connected to an input node of said second inverter,
a first storage node comprising a source node of said first pass gate device, an output of said second inverter, a second electrode of said first MIM capacitor, and a second node of said first resistor, and
a second storage node comprising a source node of said second pass gate device, an output of said first inverter, a second electrode of said second MIM capacitor, and a second node of said second resistor.

29. The memory chip of claim 28, wherein a deep NWELL region in said substrate surrounds said memory device.

30. The memory chip of claim 28, further comprising an inter-metal-dielectric (MID) layer overlying said substrate, wherein a dielectric constant of said IMD layer is less than about 3, and wherein said IMD layer includes a plurality of metal wires there within.

31. The memory chip of claim 28, further comprising a polyimide layer overlying said first dielectric layer, wherein said polyimide layer has a thickness less than about 20 microns.

32. A semiconductor chip comprising:
a silicon-on-insulator (SOI) substrate comprising
a first semiconductor layer proximate a top surface of said SOI substrate,
a second semiconductor layer underlying said first semiconductor layer,
a buried dielectric layer interposed between at least a portion of said first semiconductor layer and said second semiconductor layer, and
a memory device in said SOI substrate;
a plurality of transistors overlying said SOI substrate;
a first dielectric overlying said transistors;
a second dielectric overlying said first dielectric; and
a polyimide layer overlying said SOI substrate, said transistors, and said second dielectric, wherein a thickness of said polyimide layer is less than about 20 microns.

33. The memory chip of claim 32, wherein said first dielectric is a boron-free inter-layer-dielectric layer.

34. The memory chip of claim 32, wherein said second dielectric is an inter-metal-dielectric (IMD) layer with a dielectric constant that is less than about 3, wherein said IMD layer includes a plurality of metal wires there within.

35. The memory chip of claim 32, wherein said memory cell comprising:
a first storage node and a second storage node;
a first pass gate device electrically connected to said first storage node;
a second pass gate device electrically connected to said second storage node; and
a first inverter and a second inverter, wherein each of said inverters has an input and an output.

36. The memory chip of claim 35, further comprising:
a first metal-insulator-metal (MIM) capacitor and a second MIM capacitor, wherein a first electrode of said first MIM capacitor has a first constant voltage, and wherein a first electrode of said second MIM capacitor has a second constant voltage:
a first storage node, wherein said first storage node comprises a source node of said first pass gate device, an output of said second inverter, a second electrode of said first MIM capacitor; and
a second storage node, wherein said second storage node comprises a source node of said second pass gate device, an output of said first inverter, a second electrode of said second MIM capacitor.

37. A dynamic random access memory (DRAM) device comprising:
a voltage source having a substantially time-invariant voltage;
a bit line wire;
a substrate;
a memory cell in said substrate, said memory cell comprising
a capacitor comprising a first electrode and a second electrode, wherein said first electrode is electrically connected to said voltage source, and
a transistor comprising a drain node and a source node, wherein said drain node is electrically connected to said second electrode, and said source node is electrically connected to said bit line wire;
a boron-free inter-layer-dielectric (ILD) layer overlying said substrate; and
an inter-metal-dielectric (IMD) layer with a dielectric constant that is less tan about 3, wherein said IMD layer includes a plurality of metal wires there within.

38. The memory device of claim 37, further comprising a layer of polyimide overlying said PAD layer, wherein a thickness of said layer of polyimide is less than about 20 microns.

39. The memory device of claim 37, further comprising a un-doped oxide overlying said IMD layer, a layer of polyimide overlying said un-doped oxide, wherein a thickness of said layer of polyimide is less than about 20 microns.

40. The memory device of claim 37, wherein said plurality of metal wires comprises copper.

41. The memory device of claim 37, wherein said plurality of metal wires comprises aluminum.

42. The memory device of claim 37, wherein said plurality of metal wires comprises tungsten.

43. The memory device of claim 37, wherein said capacitor is under said IMD layer.

44. The memory device of claim 37, further comprising a fresh memory cell in said substrate.

45. The memory device of claim 37, further comprising a non-volatile memory in said substrate.

46. The memory device of claim 37, further comprising a NWELL under said memory cell.

47. A semiconductor chip comprising:
a substrate;
a first dielectric layer overlying said substrate wherein said first dielectric layer has a dielectric constant that is less than about 3, wherein said first dielectric layer includes a plurality of metal wires therein;
a polyimide layer overlying said first dielectric layer, wherein a thickness of said polyimide layer is less than about 20 microns;
a deep NWELL region in said substrate; and
an SRAM device formed in said deep NWELL region, the polyimide layer overlying a portion of said SRAM device.
